(19) United States
(12) Patent Application Publication
(10) Pub. No.: US 2026/0221169 A1
(43) Pub. Date: Jul. 30, 2026

(54) Three-Rail Memory

(71) Applicant: QUALCOMM Incorporated, San Diego, CA (US)

(72) Inventors: Xiao CHEN, San Diego, CA (US); Chulmin JUNG, San Diego, CA (US); Venugopal BOYNAPALLI, San Diego, CA (US); Prayag PATEL, San Diego, CA (US); Martin SAINT-LAURENT, Austin, TX (US); David LI, San Diego, CA (US); Anil Chowdary KOTA, San Diego, CA (US); Arun Babu PALLERLA, San Diego, CA (US); Ayan PAUL, San Diego, CA (US); Seohee KIM, San Diego, CA (US); Ravi JENKAL, San Diego, CA (US); Nate KAUFFMAN, Groton, MA (US); Abhishek Arvind SINKAR, San Diego, CA (US)

(21) Appl. No.: 19/038,629

(22) Filed: Jan. 27, 2025

(51) Int. Cl. G11C 5/14; G11C 11/418

(52) U.S. Cl. CPC G11C 5/147; G11C 11/418

(57) ABSTRACT

A three-rail memory is provided in which a core periphery is powered by a core power supply voltage. The three-rail memory also includes a bitcell array powered by a memory power supply voltage. A write driver that is powered by a bit line power supply voltage writes to the bitcell array during a write operation.

### TECHNICAL FIELD

This application relates to memories, and more particularly to a static random-access memory (SRAM) with three independent power rails.

### BACKGROUND

An integrated circuit such as a system-on-a-chip (SoC) may include various logic components. These logic components are powered by a logic power supply voltage (VDDCX) that may also be denoted as a core power supply voltage. An example logic component is a microprocessor core that uses various levels of caches to store data and instruction. The caches are generally implemented in static random-access memories (SRAMs) that are embedded within the SoC.

The use of embedded memories introduces a need for a memory power supply voltage (VDDMX) in addition to the core power supply voltage. In this fashion, the embedded memories and the logic components may be independently placed into sleep modes. To provide a better appreciation of this extra power supply voltage, note that an SRAM includes a plurality of bitcells arranged into rows and columns. A corresponding bit line pair traverses each column of bitcells. Similarly, a corresponding word line traverses each row of bitcells. The word lines, bit line pairs, and bitcells form a bitcell array that it is typically powered by the memory power supply voltage VDDMX. Because the word line and bit line capacitance may become large as the array size is increased, the bitcell array is commonly subdivided into banks, with each bank having its own rows and columns of bitcells.

An SRAM also includes various additional components besides the banks such as row and column decoders, sense amplifiers, write drivers, column multiplexers and so on to form the read and write paths to the bitcells within the banks. These additional memory components are included in what may be denoted as a memory periphery. At least a portion of the memory periphery is powered by the core power supply voltage VDDCX.

The need to maintain the stored binary values in the bitcells places a limit on how low the memory power supply voltage can be lowered to save power during a low-power mode (which may also be denoted as a light-sleep mode). In particular, the memory power supply voltage should not be lowered more than a retention level. In contrast, the core power supply voltage can be lowered below the retention level.

### SUMMARY

In accordance with an aspect of the disclosure, a system is provided that includes: a core logic circuit powered by a core power supply voltage; and a memory including: a plurality of bit line pairs; an array of bitcells arranged into rows and columns, each column being traversed by a corresponding bit line pair from the plurality of bit line pairs, each bitcell in the array of bitcells being powered by a memory power supply voltage; and a write driver configured to charge a bit line in one of the bit line pairs to a bit line power supply voltage during a write operation.

In accordance with another aspect of the disclosure, a method of powering a system is provided that includes: powering a core logic circuit with a core power supply voltage; powering an array of bitcells with a memory power supply voltage; regulating a bit line power supply voltage to be less than the memory power supply voltage using a first regulator powered by the memory power supply voltage in response to the core power supply voltage being less than a first reference voltage; and powering a word line driver with the memory power supply voltage.

In accordance with another aspect of the disclosure, a method of powering a system is provided that includes: powering a core logic circuit with a core power supply voltage; selecting between the core power supply voltage and a memory power supply voltage to provide a selected power supply voltage; powering an array of bitcells with the selected power supply voltage; regulating a bit line power supply voltage to be less than the memory power supply voltage using a first regulator powered by the memory power supply voltage in response to the core power supply voltage being less than a first reference voltage; and powering a word line driver with the bit line power supply voltage.

Finally, in accordance with yet another aspect of the disclosure, a memory is provided that includes: a memory power supply voltage rail for a memory power supply voltage; a core power supply voltage rail for a core power supply voltage; a voltage regulator coupled to the memory power supply voltage rail and the core power supply voltage rail, wherein the voltage regulator regulates a bit line power supply voltage; a bit line power supply voltage rail for the bit line power supply voltage; a bit line; a bitcell including a first inverter and a first access transistor, wherein the first inverter includes a first p-type metal-oxide semiconductor (PMOS) transistor having a source coupled to the memory power supply voltage rail, and wherein the first access transistor couples between an output node of the first inverter and the bit line; a core periphery coupled to the core power supply voltage rail; and a write driver including a second PMOS transistor having a source coupled to the bit line power supply voltage rail and a drain coupled to the bit line.

These and additional advantageous features may be better appreciated through the following detailed description.

### BRIEF DESCRIPTION OF THE DRAWINGS

FIG. 1 is a circuit diagram of a portion of a three-rail memory in accordance with an aspect of the disclosure.

FIG. 2A is a block diagram of a three-rail memory in accordance with an aspect of the disclosure.

FIG. 2B is a circuit diagram of a write driver and a column multiplexer for a three-rail memory in accordance with an aspect of the disclosure.

FIG. 3 illustrates a system including a three-rail memory in accordance with an aspect of the disclosure.

FIG. 4 illustrates a system including a three-rail memory in accordance with an aspect of the disclosure.

FIG. 5 illustrates a regulator for the bit line power voltage of a three-rail memory in accordance with an aspect of the disclosure.

FIG. 6 is a graph of the three power supply voltages for the three-rail memory of FIG. 5 in accordance with an aspect of the disclosure.

FIG. 7 illustrates a regulator for the bit line power voltage of a three-rail memory in accordance with an aspect of the disclosure.

FIG. 8 is a graph of the three power supply voltages for the three-rail memory of FIG. 7 in accordance with an aspect of the disclosure.

FIG. 9 is a flowchart for a method of powering a system including a three-rail memory in accordance with an aspect of the disclosure.

FIG. 10 illustrates some example electronic systems each incorporating a three-rail memory in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

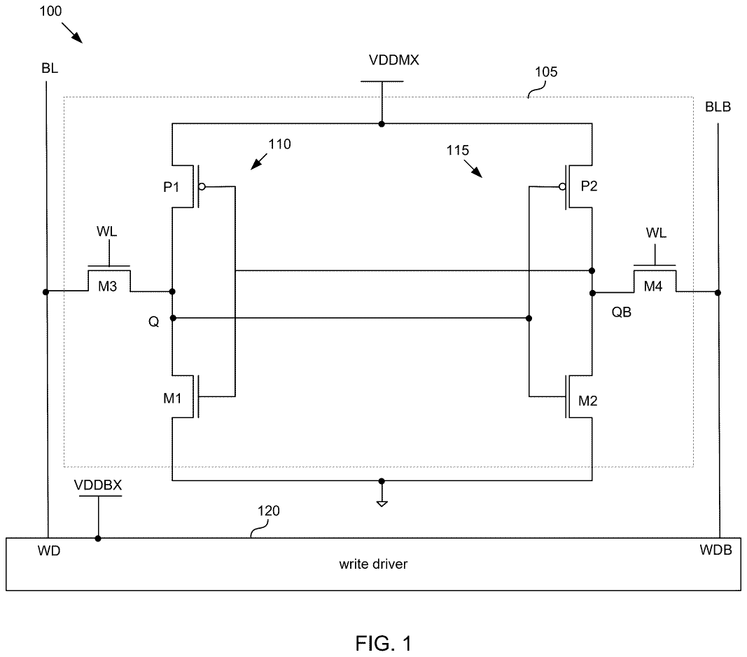

A one-port SRAM bitcell includes a pair of cross-coupled inverters formed by four transistors for latching a binary value (also denoted herein as a bit). A pair of access transistors forms a single access port for both read and write operations so that the total number of transistors to construct a single-port SRAM bitcell is six transistors. An example memory 100 with an SRAM bitcell 105 is shown in FIG. 1 that includes a pair of cross-coupled inverters 110 and 115. The inverter 110 includes a p-type metal-oxide semiconductor (PMOS) transistor P1 in series with an n-type metal-oxide semiconductor (NMOS) transistor M1. The drains of the transistors P1 and M1 form an output node Q for the inverter 110 that drives a voltage for a stored bit Q for the bitcell 100. The inverter 115 is analogous in that it includes a PMOS transistor P2 in series with an NMOS transistor M2. The drains of the transistors P2 and M2 form a complement output node QB for the inverter 115 that drives a voltage of a stored complement bit QB for the bitcell 105. Transistor P10 is also denoted herein as a first PMOS transistor.

The output node Q couples through an NMOS access transistor M3 to a bit line bl. Similarly, the output node QB couples through an NMOS access transistor M4 to a complement bit line blb. A word line WL couples to the gates of the access transistors M3 and M4. During a read or write operation, a voltage of the word line WL is asserted to the memory power supply voltage to switch on the access transistors so that the bit line bl is connected with the node for the bit Q and so that the complement bit line blb is connected with the node for the complement bit QB. During a write operation, a write driver 120 drives the bit line BL with a write driver WD signal and drives the complement bit line BLB with a complement write driver signal WDB. With the access transistors M3 and M4 switched on, the write driver 120 may then write to the bitcell 105.

Prior to a write operation, the bit lines BL and BLB are pre-charged. The write driver signals WD and WDB are binary complements of each other (one being a binary one and the other a binary zero) so one of the bit lines is then discharged during a write operation. Since the bit lines extend across a column of bitcells (not shown in FIG. 1), the bit line capacitance is non-negligible such that the bit line power consumed by the pre-charging and discharging of the bit lines is a significant factor in the memory power consumption. In contrast, the output nodes Q and QB have a lower capacitance as compared to the bit lines. The bitcell power consumption may thus be relatively minor as compared to the bit line power consumption. As noted earlier, at least a portion of the memory periphery is powered by the core power supply voltage. The portion of the memory periphery powered by the core power supply voltage is thus denoted herein as a core periphery. To reduce the bit line power consumption, the write driver 120 could be powered by the core power supply voltage (not shown in FIG. 1). But note that even in a low-power mode in which the memory power supply voltage is reduced, the bitcell 105 must retain its stored binary content. Hence, a minimum value (the retention value) for the memory power supply voltage is greater than a low-power mode value for the core power supply voltage. The retention value for the memory power supply voltage will depend upon the semiconductor process node but in some implementations, the retention value of the memory power supply voltage is approximately 0.65V. In contrast, a low-power mode value of the core power supply voltage may be significantly lower such as 0.4V.

But note the problem should the core power supply voltage be used to pre-charge the bit lines during a low-power mode for the core power supply voltage. If the bit lines are pre-charged to no more than 0.4V while the memory power supply voltage is maintained at its retention level of 0.65V, a write operation may be unsuccessful. The retention value of the memory power supply voltage thus places a constraint on how low the core power supply voltage may be lowered should the core power supply voltage be used to power the bit lines. This constraint undesirably limits how low the core power supply voltage can be lowered for an SoC's logic core during low-power modes. Should the core power supply voltage be too low as compared to the memory power supply voltage, a write operation may fail since the write driver 120 will be unable to flip the stored binary content of the bitcell 105. Conversely, if the core power supply voltage is greater than the memory power supply (assuming that the core power supply voltage is used to charge the bit lines), this increased core power supply voltage may cause an unintended reversal of a bitcell's stored binary content. The core power supply voltage thus cannot be raised above the memory power supply voltage to support a high-performance mode for the logic core.

To remove the inter-dependencies between the core power supply voltage and the memory power supply voltage, a separate (third) power supply voltage (referred to herein as bit line power supply voltage) is provided so as not to impair the memory writing and/or retention capabilities of the bitcell. The core power supply voltage may be varied independently with respect to the memory power supply voltage and may thus advantageously be increased to be greater than the memory power supply voltage during a high-performance mode for the logic core. Similarly, the memory power supply voltage may be varied independently with respect to the core power supply voltage. A logic core of an SoC including the memory 100 may thus save power through low-power modes despite the memory 100 maintaining the memory power supply voltage at the retention level. Moreover, the memory 100 saves significant power by lowering the bit line power supply voltage with respect to the memory power supply voltage. Although it is denoted herein as the bit line power supply voltage, the bit line power supply voltage may power additional components in the memory periphery besides the write driver 120. Memory 100 may also be denoted as a three-rail memory since it has three separate power supply voltages VDDMX, VDDCX, and VDDBX.

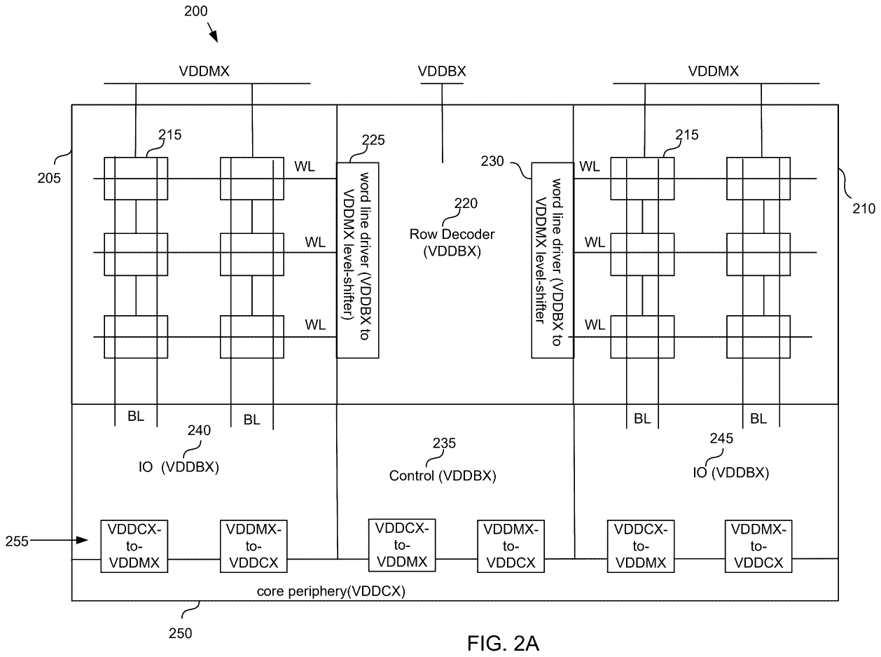

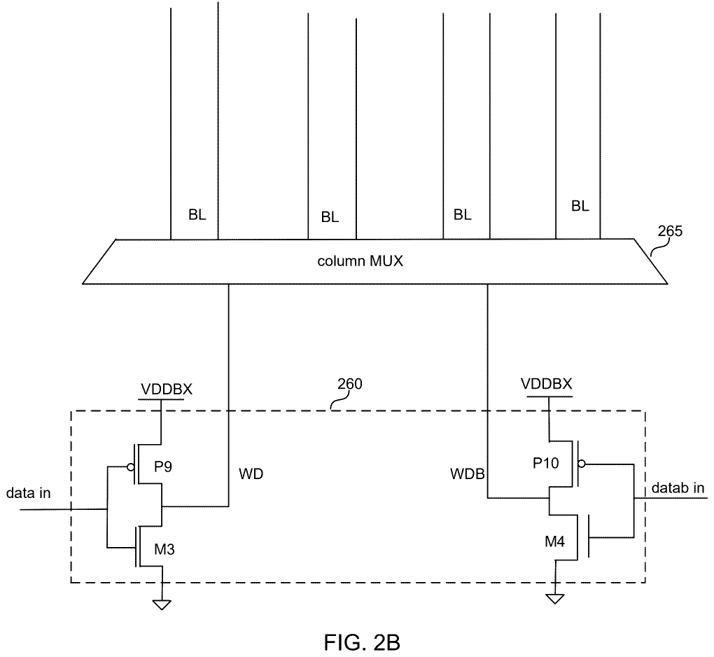

Another example three-rail memory 200 is shown in more detail in FIG. 2A. In memory 200, a plurality of bitcells 215 is arranged into a first bank 205 and a second bank 210. Within each bank, the bitcells are arranged into rows and columns with each row traversed by a corresponding word line WL and each column traversed by a pair of bit lines designated collectively as BL. It will be appreciated, however, that each pair of bit lines includes a true bit line and a complement bit line as discussed with regard to memory 100. The arrangement of the bitcells 215 into separate banks reduces the bit line and word line length so that the memory speed is not slowed down by excessive word line and bit line capacitance. However, the three rails disclosed herein may be implemented in memories having only a single bitcell array in alternative implementations.

The bitcells 215 are powered by the memory power supply voltage (VDDMX) as also discussed for memory 100. A row decoder 220 that is powered by the bit line power supply voltage (VDDBX) decodes row addresses to drive the corresponding one or more word lines in the addressed one of the banks 205 and 210. In some implementations, the word line voltage for the addressed word line may then be asserted to the bit line power supply voltage. However, the application of the bit line power supply voltage to the addressed one or more word lines in memory 200 may not provide a sufficient write margin. In such implementations, a word line driver 225 for the bank 205 may level-shift from the bit line power supply voltage to the memory power supply voltage to drive the selected word line. Similarly, a word line driver 230 for the bank 210 also level-shifts from the bit line power supply voltage to the memory power supply voltage to drive the selected word line.

A control circuit 235 for the memory 200 is also powered by the bit line power supply voltage. For example, the control circuit 235 may control the various clock signals (not illustrated) that control the operation of memory 200. An IO circuit 240 for the bank 205 is also powered by the bit line power supply voltage. The bit lines BL for the bank 215 are thus pre-charged to the bit line power supply voltage prior to a write operation. The IO circuit 240 includes a write driver (not illustrated) that drives a bit line pair for a selected column in the bank 205 during a write operation. Depending upon the bit being written, one bit line in the bit line pair of the selected column will be maintained at its pre-charged state of the bit line power supply voltage whereas a complementary one of the bit lines in the selected column is discharged to ground. As noted previously, the bit lines must traverse their column to couple to all of the column's bitcells 215. Thus, each bit line has an appreciable amount of capacitance so that power is consumed with respect to pre-charging a bit line prior to a write operation and then discharging the bit line to ground during the write operation. But this power consumption is advantageously reduced in the memory 200 due to the usage of the bit line power supply voltage because the bit line power supply voltage may be lowered as compared to the memory power supply voltage depending upon the mode of operation. For example, the memory power supply voltage cannot be reduced below its retention value during a light-sleep mode of operation. In contrast, the bit line power supply voltage may be reduced below the retention value during the light-sleep mode of operation to save power.

The IO circuit 240 also includes column multiplexers (not illustrated) that couple the write driver to the column and also includes sense amplifiers (not illustrated) to sense the bit lines in the selected column during a read operation. Since these components in the IO circuit 240 are powered by the bit line power supply voltage, their power consumption may be reduced as compared to powering these components with the memory power supply voltage. An IO circuit 245 for the bank 210 is analogous and is thus also powered by the bit line power supply voltage.

During a write operation, a logic core circuit (not illustrated) such as a central processing unit (CPU (or a graphics processing unit GPU or other suitable source) generates a data input signal to be written to the selected one of the banks 205 and 210. A core periphery 250 for the memory 200 is also in the core power domain and is thus powered by the core power supply voltage (VDDCX). As defined herein, the core periphery 250 is the portion of the memory periphery that is powered by the core power supply voltage. A plurality of level-shifters 255 includes a VDDCX-to-VDDBX level-shifter for each of the IO circuits 240 and 245 to level-shift, for example, the data in signal from the core power supply voltage to the bit line power supply voltage. Similarly, the plurality of level-shifters 255 includes a VDDBX-to-VDDCX level-shifter for each of the IO circuits 240 and 245 to, for example, level-shift a data out signal from the bit line power supply voltage to the core power supply voltage during read operations. The plurality of level-shifters 255 also includes a VDDBX-to-VDDCX level-shifter and a VDDCX-to-VDDBX level-shifter for the flow of control signals between the control circuit 235 and the core periphery 250. It will be appreciated that each level-shifter shown in memory 200 may instead represent a plurality of level-shifters.

A write driver 260 for one of the IO circuits 240 or 245 and an associated column multiplexer 265 is shown in FIG. 2B. The write driver 260 includes a first inverter formed by a PMOS transistor P9 in series with an NMOS transistor M3. A source of the transistor P9 couples to a bit line power supply voltage rail for the bit line power supply voltage. Transistor P9 is also denoted herein as a second PMOS transistor. A source of the transistor M3 couples to ground. A data in signal couples to the gates of the transistors P9 and M3 to form a write driver signal WD at the drains of the transistors P9 and M3. The drains of the transistors P9 and M3 couple through the column multiplexer 265 to a bit line in a selected bit line pair. Similarly, the write driver 260 includes a second inverter formed by a PMOS transistor P10 in series with an NMOS transistor M4. A source of the transistor P10 couples to the bit line power supply voltage rail whereas a source of the transistor M4 couples to ground. A complement data in signal (datab in) couples to the gates of the transistors P10 and M4 to form a complement write driver signal WDB at the drains of the transistors P10 and M4. The drains of the transistors P10 and M4 couple through the column multiplexer 265 to a complement bit line in the selected bit line pair.

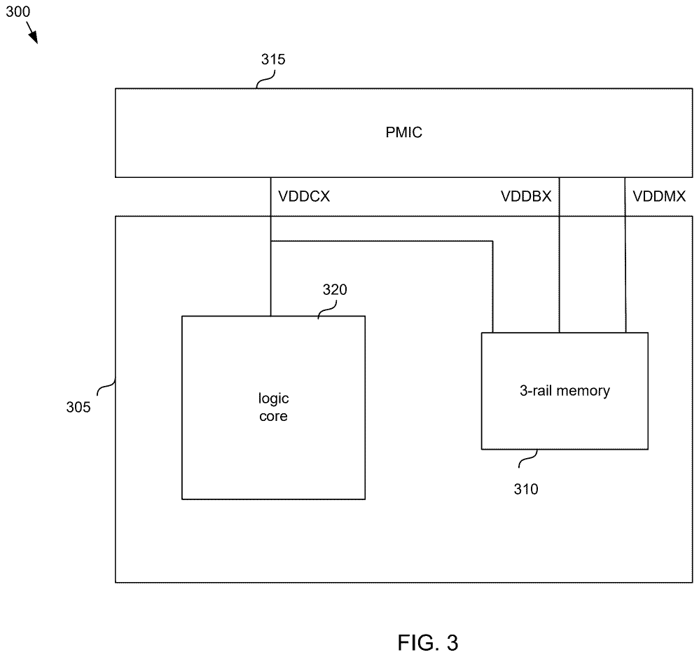

A system 300 including an SoC 305 having a three-rail memory 310 is shown in FIG. 3. SoC 305 also includes a logic core circuit 320 such as a CPU or a GPU powered by the core power supply voltage. A power management integrated circuit (PMIC) 315 regulates the three power supply voltages VDDMX, VDDBX, and VDDCX. The PMIC 315 may regulate the bit line power supply voltage according to the constraints that traditionally would be applied to the core power supply voltage's relationship to the memory power supply voltage. But because of the inclusion of the bit line power supply voltage, the core power supply voltage may be varied without any constraints with respect to the memory power supply voltage. Similarly, the memory power supply voltage may be varied without any constraints with respect to the core power supply voltage. But note again that the memory power supply voltage cannot be lowered below a retention level during a low-power mode (the memory power supply voltage may be discharged to ground, however, during a deep-sleep mode in which the stored data is lost).

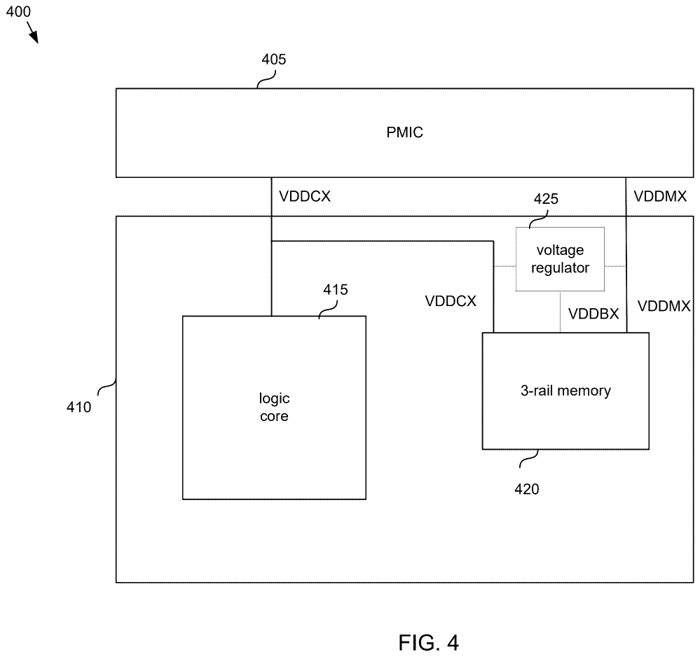

In an alternative system 400 shown in FIG. 4, a PMIC 405 need only regulate the core power supply voltage and the memory power supply voltage. An SoC 410 includes a logic core circuit 415 (e.g., a CPU or a GPU) and a three-rail memory 420 analogously as discussed for system 300. A bit line power supply voltage regulator 425 that is powered by the core power supply voltage and the memory power supply voltage regulates the bit line power supply voltage. The regulation of the bit line power supply voltage by the bit line power supply voltage regulator 425 varies depending upon the implementation. For example, the regulation may vary depending upon whether bulk read or bulk write operations are implemented. A low-power consumption implementation will first be discussed followed by a discussion of a high-performance implementation.

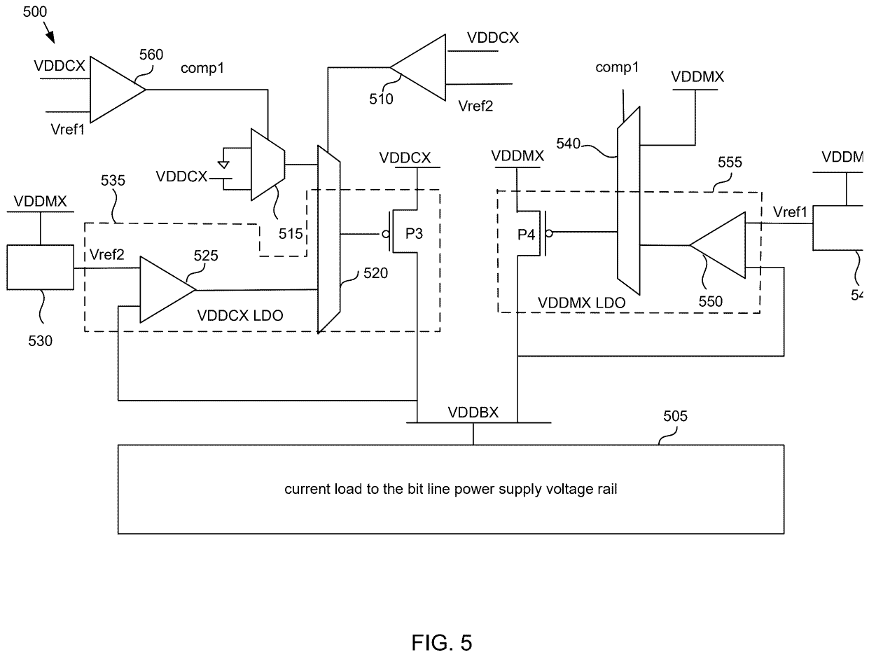

A low-power bit line power supply voltage regulator 500 for a memory represented by a current load to the bit line power supply voltage rail 505 is shown in FIG. 5. A VDDCX LDO 535 operates when selected by a multiplexer 520. The VDDCX LDO 535 includes a PMOS transistor P3 having a gate voltage controlled by a differential amplifier 525. The differential amplifier 525 amplifies a voltage difference between a drain voltage of the transistor P3 and a second reference voltage Vref2 produced by a reference voltage source 530 that is powered by the memory power supply voltage VDDMX. In one implementation, the second reference voltage may equal 0.75V although the second reference voltage may be greater than or less than 0.75V in alternative implementations. To control whether the VDDCX LDO 535 is active or switched off, a comparator 510 compares the core power supply voltage to second reference voltage. Should the core power supply voltage be greater than the second reference voltage, the VDDCX LDO 535 is active to produce the bit line power supply voltage at the drain of the transistor P3. A source of the transistor P3 couples to a node for the core power supply voltage. The transistor P3 is also denoted herein as a first transistor.

Should instead the core power supply voltage be less than the second reference voltage, the comparator 510 controls the multiplexer 520 to instead select an output signal from a multiplexer 515. To control the multiplexer 515, a comparator 560 compares the core power supply voltage to a first reference voltage (Vref1) from a voltage source 545 that is also powered by the memory power supply voltage to produce a comparator output signal comp1. In general, the first reference voltage is less than the second reference voltage. In one implementation, the first reference voltage may equal 0.55V but it will be appreciated that the first reference voltage may be greater than or less than 0.55V in alternative implementations. The comparator output signal comp1 controls the multiplexer 515 to select for ground should the core power supply voltage be greater than the first reference voltage. Since the multiplexer 520 is in turn controlled by the comparator 510, the transistor P3 will be fully on when the inequality Vref1<VDDCX<Vref2 is satisfied such that the bit line power supply voltage then equals the core power supply voltage. Should instead the core power supply voltage be greater than the second reference voltage, the transistor P3 will be partially on as controlled by the VDDCX LDO 535 to maintain the core power supply voltage to equal the second reference voltage. The VDDCX LDO 535 is also denoted herein as a second regulator.

The comparator output signal comp1 also controls a multiplexer 540 so that a VDDMX LDO 555 is active when the core power supply voltage is less than the first reference voltage. The VDDMX LDO 555 includes a PMOS transistor P4 having a source coupled to a node for the memory power supply voltage. A drain of the transistor P4 couples to the bit line power supply voltage rail. A differential amplifier 550 amplifies a difference between the bit line power supply voltage and the first reference voltage to control a gate voltage of the transistor P4 so that the bit line power supply voltage is regulated to equal the first reference voltage when the core power supply voltage is less than the first reference voltage. Should the core power supply voltage rise above the first reference voltage, the multiplexer 540 selects for the memory power supply voltage so as to shut off the VDDMX LDO 555. The VDDMX LDO 555 is also denoted herein as a first regulator.

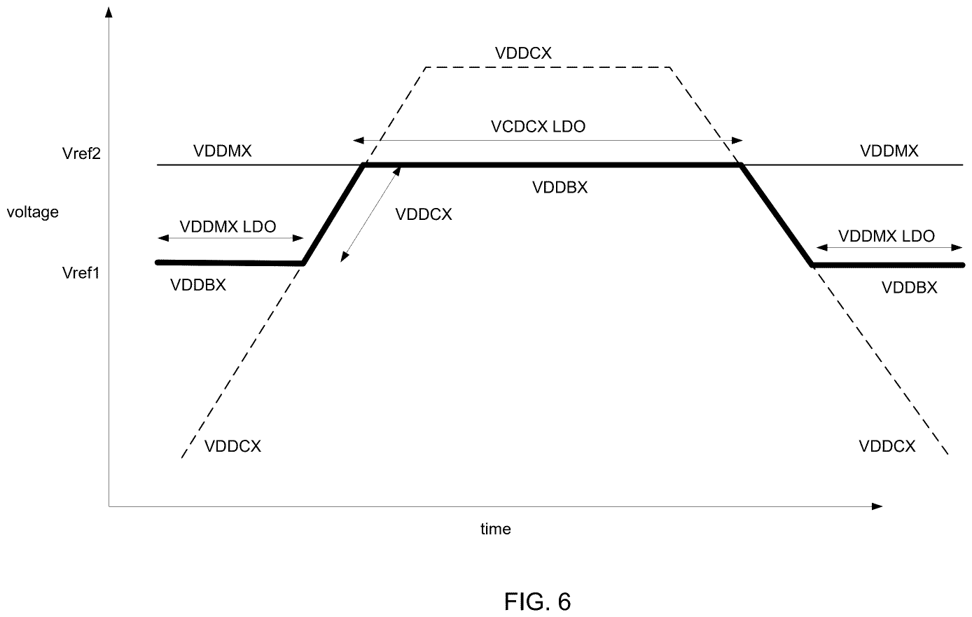

A graph of the various power supply voltages for the memory of FIG. 5 as a function of time is shown in FIG. 6. Should the core power supply voltage be less than the first reference voltage, the VDDMX LDO 555 is active to regulate the core power supply voltage to equal the first reference voltage. As used herein, a voltage regulator such as the LDO 555 is deemed “to regulate” a voltage so as to maintain the voltage to equal a desired value. When the core power supply voltage is greater than the first reference voltage and less than the second reference voltage, the VDDMX LDO 555 is off and the bit line power supply volage equals the core power supply voltage. As the core power supply voltage rises above the second reference voltage, the VDDCX LDO 535 becomes active to regulate the bit line power supply voltage to equal the second reference voltage. When the core power supply voltage then drops below the second reference voltage but is greater than the first reference voltage, the VDDCX and VDDMX LDOs are off and the bit line power supply voltage equals the core power supply voltage. Finally, when the core power supply voltage drops below the first reference voltage, the VDDMX LDO 555 is again active to regulate the bit line power supply voltage to equal the core power supply voltage.

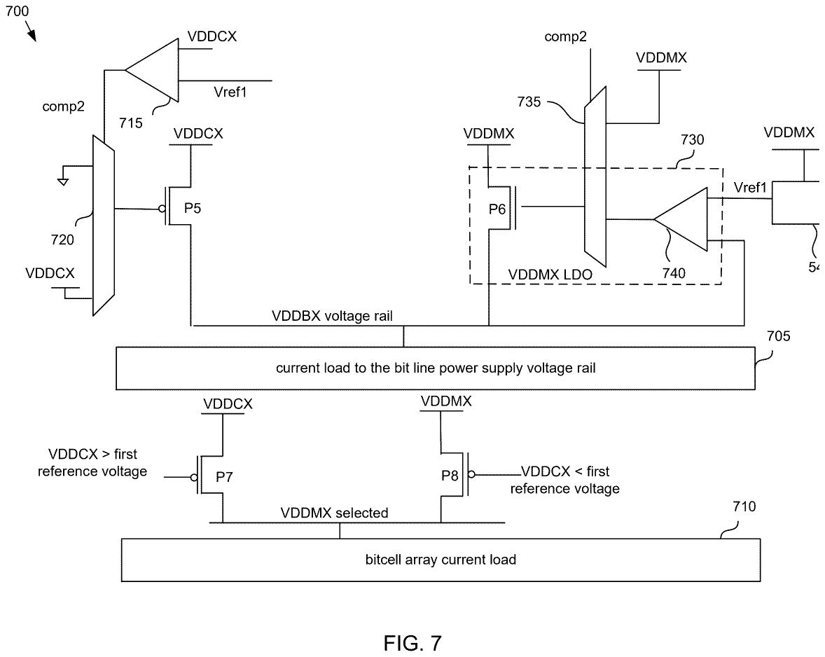

In the high-performance implementation, the memory not only includes a regulator for the bit line power supply voltage but also regulates a selected memory power supply voltage designated herein as a VDDMX selected voltage and also as a selected power supply voltage. An example high-performance voltage regulator 700 for a memory represented by a current load to the bit line power supply voltage rail 705 and a bitcell array current load 710 is shown in FIG. 7. The reference voltage source 545 produces the first reference voltage as discussed previously. A comparator 715 compares the core power supply voltage to the first reference voltage to drive a comparator signal comp2 to control a multiplexer 720 to select for ground should the core power supply voltage be greater than the first reference voltage. The selected ground drives a gate of a PMOS transistor P5 having a source coupled to a node for the core power supply voltage and a drain coupled to the bit line power supply voltage rail. The transistor P5 thus switches on should the core power supply voltage be greater than the first reference voltage to force the bit line power supply voltage to equal the core power supply voltage. Should the core power supply voltage drop below the first reference voltage, the comparator 715 controls the multiplexer 720 to select for the core power supply voltage to switch off the transistor P5. The transistor P5 is also denoted herein as a second transistor.

The comparator signal comp2 also controls a multiplexer 735 to select for an output signal of a differential amplifier 740 in a VDDMX LDO 730 in response to the core power supply voltage dropping below the first reference voltage. The VDDMX LDO 730 includes a PMOS transistor P6 whose gate voltage is controlled by the output signal of the differential amplifier 740. A source of the transistor P6 couples to a node for the memory power supply voltage. A drain of the transistor P6 couples to the bit line power supply voltage rail. The bit line power supply voltage is thus regulated by the VDDMX LDO 730 to equal the first reference voltage in response to the core power supply voltage dropping below the first reference voltage.

To enable a high-performance mode for the corresponding memory, the high-performance voltage regulator 700 also includes a PMOS transistor P7 that couples between a node for the core power supply voltage and a VDDMX selected voltage rail for the bitcell array represented by the bitcell array current load 710. A comparator (not illustrated) controls the transistor P7 to switch on should the core power supply voltage be greater than the first reference voltage. A VDDMX selected power supply voltage to power the bitcell array will then equal the core power supply voltage as the core power supply voltage rises above the first reference voltage. Similarly, the high-performance voltage regulator 700 also includes a PMOS transistor P8 that couples between a node for the memory power supply voltage and the VDDMX selected voltage rail. A comparator (not illustrated) controls a gate voltage of the transistor P8 to switch the transistor P8 on in response to the core power supply voltage dropping below the second reference voltage. The VDDMX selected power supply voltage will thus equal the memory power supply voltage should the core power supply voltage dip below the second reference voltage.

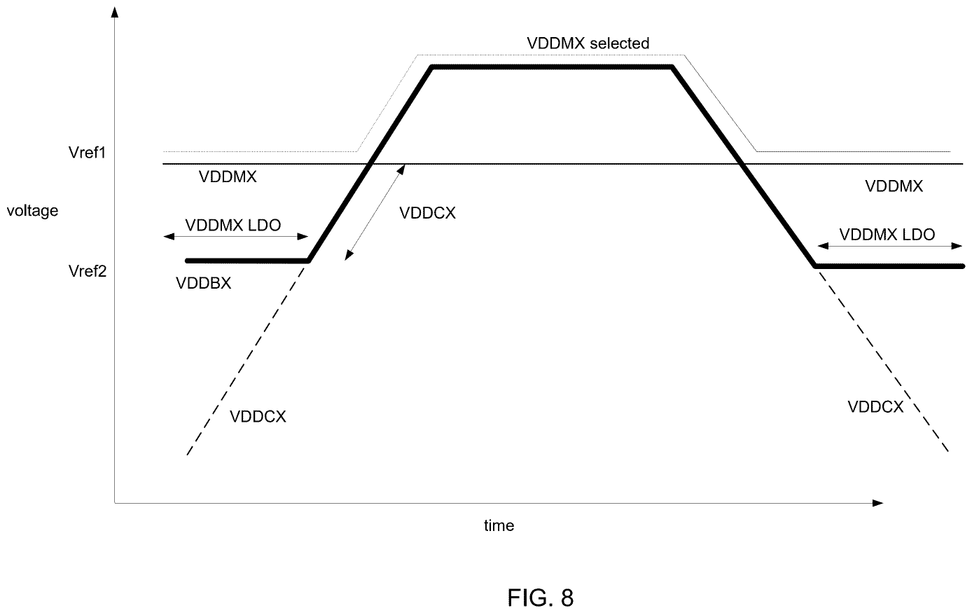

A graph of the various power supply voltages for the memory of FIG. 7 as a function of time as controlled by the high-performance regulator 700 is shown in FIG. 8. Initially, the core power supply voltage is less than the first reference voltage. The VDDMX LDO 730 thus regulates the bit line power supply voltage to equal the first reference voltage. As the core power supply voltage rises above the first reference voltage, the bit line power supply voltage equals the core power supply voltage, even as the core power supply voltage rises above the second reference voltage. After a period of high performance with the bit line power supply voltage being greater than the second reference voltage, the core power supply voltage then begins to decrease. While the core power supply voltage decreases but is above the first reference voltage, the bit line power supply voltage equals the core power supply voltage. But when the core power supply voltage decreases below the first reference voltage, the VDDMX LDO 730 again regulates the bit line power supply voltage to equal the first reference voltage.

The VDDMX selected power supply voltage is also shown in FIG. 8. While the core power supply voltage is lower than the second reference voltage, the VDDMX selected power supply voltage equals the memory power supply voltage (for illustration clarity, the VDDMX selected power supply voltage is shown in FIG. 8 as being slightly greater than its actual value). But when the core power supply voltage rises above the second reference voltage, the VDDMX selected power supply voltage equals the core power supply voltage.

It will thus be appreciated that a three-rail memory in which the bit line power supply domain and the bitcell power domain are controlled by the high-performance regulator 700, the three-rail memory is actually a four-rail memory in that there are four power supply voltages: VDDCX, VDDMX, VDDBX, and VDDMX selected. However, since the VDDMX selected power supply voltage always equals either the core power supply voltage or the memory power supply voltage, there are only three independent power supply voltages.

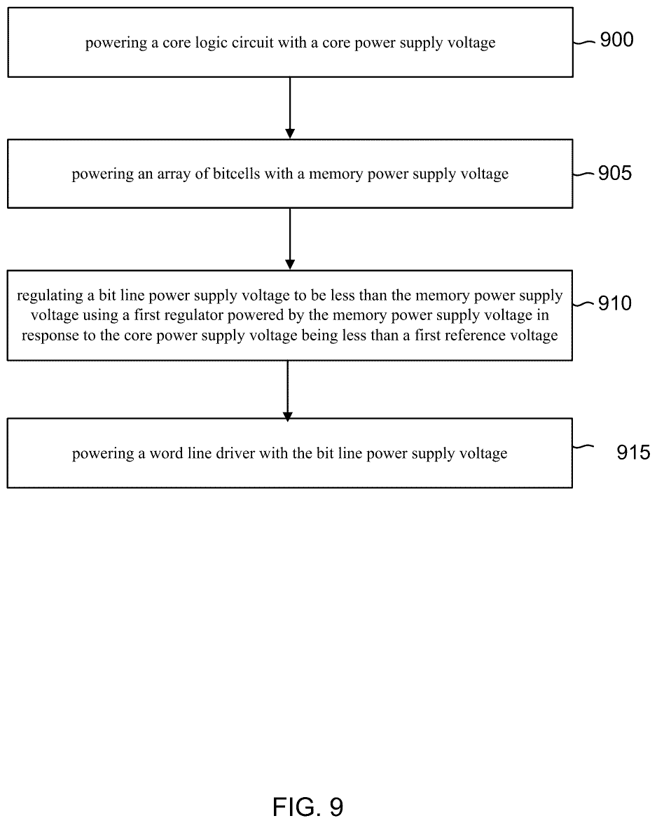

A method of powering a system including a three-rail memory will now be discussed with respect to the flowchart of FIG. 9. The method includes an act 900 of powering a core logic circuit with a core power supply voltage. The powering of the core logic circuit 320 or 415 is an example of act 900. The method further includes an act 905 of powering an array of bitcells with a memory power supply voltage. The powering of the bitcells 215 is an example of act 905. The method also includes an act 910 of regulating a bit line power supply voltage to be less than the memory power supply voltage using a first regulator powered by the memory power supply voltage in response to the core power supply voltage being less than a first reference voltage. The regulation of the bit line power supply voltage by the VDDMX LDO 555 is an example of act 910. Finally, the method includes an act 915 powering a word line driver with the memory power supply voltage. The powering of the bit line driver 260 is an example of act 915.

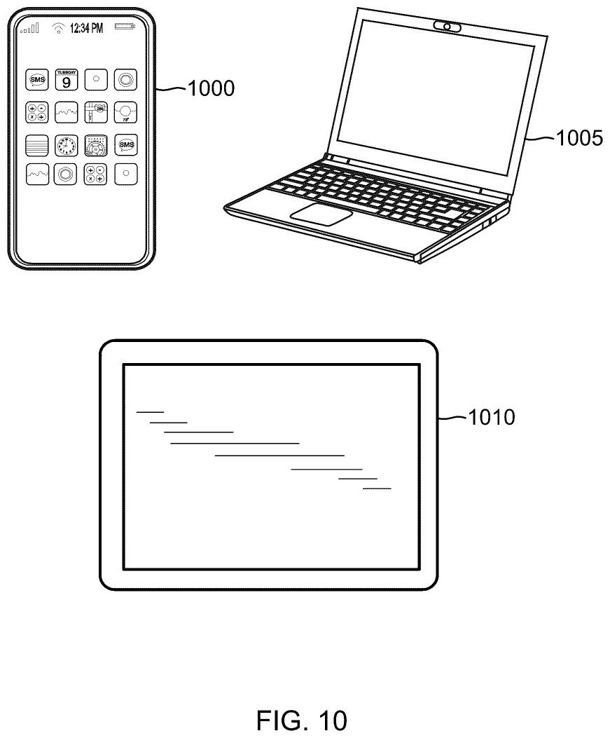

An SoC including a three-rail memory as disclosed herein may be incorporated into a wide variety of electronic systems. For example, as shown in FIG. 10, a cellular telephone 1000, a laptop computer 1005, and a tablet PC 1010 may all include an SoC having a three-rail memory in accordance with the disclosure. Other exemplary electronic systems such as a music player, a video player, a communication device, and a personal computer may also be configured with three-rail memories constructed in accordance with the disclosure.

Some aspects of the disclosure will now be summarized in the following series of example clauses:
Clause 1. A system, comprising:
   a core logic circuit powered by a core power supply voltage; and
   a memory including:
      a plurality of bit line pairs;
      an array of bitcells arranged into rows and columns, each column being traversed by a corresponding bit line pair from the plurality of bit line pairs, each bitcell in the array of bitcells being powered by a memory power supply voltage; and
      a write driver configured to charge a bit line in one of the bit line pairs to a bit line power supply voltage during a write operation.
Clause 2. The system of clause 1, further comprising:
   a power management integrated circuit configured to regulate the core power supply voltage, the bit line power supply voltage, and the memory power supply voltage.
Clause 3. The system of any of clauses 1-2, wherein the system comprises a system-on-a-chip.
Clause 4. The system of clause 1, further comprising:
   a bit line power supply voltage regulator configured to regulate the bit line power supply voltage, wherein the bit line power supply voltage regulator is powered by the core power supply voltage and a memory power supply voltage.
Clause 5. The system of clause 4, further comprising:
   a plurality of word lines, each row being traversed by a corresponding word line pair from the plurality of word lines;
   a row decoder powered by the bit line power supply voltage and configured to select one of the rows during the write operation; and
   a word line driver configured to charge the selected one of the row's corresponding word line to the memory power supply voltage.
Clause 6. The system of any of clauses 4-5, wherein the memory further includes a core logic periphery powered by the core power supply voltage.
Clause 7. The system of clause 5, wherein the array of bitcells is subdivided into a first bank and a second bank, and wherein the row decoder and the word line driver are located between the first bank and the second bank.
Clause 8. The system of clause 6, wherein the memory further includes a control circuit powered by the bit line power supply voltage.
Clause 9. The system of clause 8, further comprising:
   a first level-shifter configured to level-shift signals from the control circuit, wherein the first level-shifter is configured to shift from the bit line power supply voltage to the core power supply voltage; and
   a second level-shifter configured to level-shift signals from the core logic circuit, wherein the second level-shifter is configured to shift from the core power supply voltage to the bit line power supply voltage.
Clause 10. The system of any of clauses 1-96, wherein the core logic circuit comprises a central processing unit.
Clause 11. The system of any of clauses 1-10, wherein the core logic circuit comprises a graphics processing unit.
Clause 12. A method of powering a system, comprising:
   powering a core logic circuit with a core power supply voltage;
   powering an array of bitcells with a memory power supply voltage;
   regulating a bit line power supply voltage to be less than the memory power supply voltage using a first regulator powered by the memory power supply voltage in response to the core power supply voltage being less than a first reference voltage; and
   powering a word line driver with the memory power supply voltage.
Clause 13. The method of clause 12, wherein regulating the bit line power supply voltage to be less than the memory power supply voltage comprises regulating the bit line power supply voltage to equal the first reference voltage.
Clause 14. The method of any of clauses 12-13, further comprising:
   regulating the bit line power supply voltage to equal a second reference voltage using a second regulator powered by the core power supply voltage in response to the core power supply voltage being greater than a second reference voltage.
Clause 15. The method of clause 14; further comprising:
   switching on a first transistor coupled between a bit line power supply voltage rail for the bit line power supply voltage and a core power supply voltage rail for the core power supply voltage in response to the core power supply voltage being greater the first reference voltage and less than the second reference voltage.
Clause 16. The method of any of clauses 12-15, further comprising:
   switching on a second transistor coupled between a bit line power supply voltage rail for the bit line power supply voltage and a core power supply voltage rail for the core power supply voltage in response to the core power supply voltage being greater the first reference voltage.
Clause 17. A method of powering a system, comprising:
   powering a core logic circuit with a core power supply voltage;
   selecting between the core power supply voltage and a memory power supply voltage to provide a selected power supply voltage;
   powering an array of bitcells with the selected power supply voltage;
   regulating a bit line power supply voltage to be less than the memory power supply voltage using a first regulator powered by the memory power supply voltage in response to the core power supply voltage being less than a first reference voltage; and
   powering a word line driver with the memory power supply voltage.
Clause 18. The method of clause 17, wherein selecting between the core power supply voltage and the memory power supply voltage to provide the selected power supply voltage comprises:
   passing the memory power supply voltage to form the selected power supply voltage in response to the core power supply voltage being less than a second reference voltage; and
   passing the core power supply voltage to form the selected power supply voltage in response to the core power supply voltage being greater than the second reference voltage.
Clause 19. The method of clause 18, wherein the second reference voltage is greater than the first reference voltage.
Clause 20. The method of clause 18, wherein the first reference voltage approximately equals 0.55V and the second reference voltage approximately equals 0.75V.
Clause 21. A memory, comprising:
   a memory power supply voltage rail for a memory power supply voltage;
   a core power supply voltage rail for a core power supply voltage;
   a voltage regulator coupled to the memory power supply voltage rail and the core power supply voltage rail, wherein the voltage regulator regulates a bit line power supply voltage;
   a bit line power supply voltage rail for the bit line power supply voltage;
   a bit line;
   a bitcell including a first inverter and a first access transistor, wherein the first inverter includes a first p-type metal-oxide semiconductor (PMOS) transistor having a source coupled to the memory power supply voltage rail, and wherein the first access transistor couples between an output node of the first inverter and the bit line;
   a core periphery coupled to the core power supply voltage rail; and
   a write driver including a second PMOS transistor having a source coupled to the bit line power supply voltage rail and a drain coupled to the bit line.
Clause 22. The memory of clause 21, wherein the write driver further includes an NMOS transistor having a source coupled to ground and a drain coupled to the drain of the second PMOS transistor.
Clause 23. The memory of any of clauses 21-22, further comprising:
   a column multiplexer, wherein the drain of the second PMOS transistor is coupled to the bit line through the column multiplexer.
Clause 24. The memory of any of clauses 21-23, further comprising:
   a word line;
   a row decoder powered by a bit line power supply voltage from the bit line power supply voltage rail and configured to select for the word line during a write operation to the memory; and
   a word line driver configured to charge the word line to the memory power supply voltage.
Clause 25. The memory of any of clauses 21-24, wherein the memory is included within a system-on-a-chip.
Clause 26. The memory of clause 25, wherein the system-on-a-chip is included within a cellular telephone.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A system, comprising:
a core logic circuit powered by a core power supply voltage; and
a memory including:
a plurality of bit line pairs;
an array of bitcells arranged into rows and columns, each column being traversed by a corresponding bit line pair from the plurality of bit line pairs, each bitcell in the array of bitcells being powered by a memory power supply voltage; and
a write driver configured to charge a bit line in one of the bit line pairs to a bit line power supply voltage during a write operation.

2. The system of claim 1, further comprising:
a power management integrated circuit configured to regulate the core power supply voltage, the bit line power supply voltage, and the memory power supply voltage.

3. The system of claim 1, wherein the system comprises a system-on-a-chip.

4. The system of claim 1, further comprising:
a bit line power supply voltage regulator configured to regulate the bit line power supply voltage, wherein the bit line power supply voltage regulator is powered by the core power supply voltage and a memory power supply voltage.

5. The system of claim 4, further comprising:
a plurality of word lines, each row being traversed by a corresponding word line pair from the plurality of word lines;
a row decoder powered by the bit line power supply voltage and configured to select one of the rows during the write operation; and
a word line driver configured to charge the selected one of the row's corresponding word line to the memory power supply voltage.

6. The system of claim 4, wherein the memory further includes a core logic periphery powered by the core power supply voltage.

7. The system of claim 5, wherein the array of bitcells is subdivided into a first bank and a second bank, and wherein the row decoder and the word line driver are located between the first bank and the second bank.

8. The system of claim 6, wherein the memory further includes a control circuit powered by the bit line power supply voltage.

9. The system of claim 8, further comprising:
a first level-shifter configured to level-shift signals from the control circuit, wherein the first level-shifter is configured to shift from the bit line power supply voltage to the core power supply voltage; and
a second level-shifter configured to level-shift signals from the core logic circuit, wherein the second level-shifter is configured to shift from the core power supply voltage to the bit line power supply voltage.

10. The system of claim 1, wherein the core logic circuit comprises a central processing unit.

11. The system of claim 1, wherein the core logic circuit comprises a graphics processing unit.

12. A method of powering a system, comprising:
powering a core logic circuit with a core power supply voltage;
powering an array of bitcells with a memory power supply voltage;
regulating a bit line power supply voltage to be less than the memory power supply voltage using a first regulator powered by the memory power supply voltage in response to the core power supply voltage being less than a first reference voltage; and
powering a word line driver with the memory power supply voltage.

13. The method of claim 12, wherein regulating the bit line power supply voltage to be less than the memory power supply voltage comprises regulating the bit line power supply voltage to equal the first reference voltage.

14. The method of claim 12, further comprising:
regulating the bit line power supply voltage to equal a second reference voltage using a second regulator powered by the core power supply voltage in response to the core power supply voltage being greater than a second reference voltage.

15. The method of claim 14; further comprising:
switching on a first transistor coupled between a bit line power supply voltage rail for the bit line power supply voltage and a core power supply voltage rail for the core power supply voltage in response to the core power supply voltage being greater the first reference voltage and less than the second reference voltage.

16. The method of claim 12, further comprising:
switching on a second transistor coupled between a bit line power supply voltage rail for the bit line power supply voltage and a core power supply voltage rail for the core power supply voltage in response to the core power supply voltage being greater the first reference voltage.

17. A method of powering a system, comprising:
powering a core logic circuit with a core power supply voltage;
selecting between the core power supply voltage and a memory power supply voltage to provide a selected power supply voltage;
powering an array of bitcells with the selected power supply voltage;
regulating a bit line power supply voltage to be less than the memory power supply voltage using a first regulator powered by the memory power supply voltage in response to the core power supply voltage being less than a first reference voltage; and
powering a word line driver with the memory power supply voltage.

18. The method of claim 17, wherein selecting between the core power supply voltage and the memory power supply voltage to provide the selected power supply voltage comprises:
passing the memory power supply voltage to form the selected power supply voltage in response to the core power supply voltage being less than a second reference voltage; and
passing the core power supply voltage to form the selected power supply voltage in response to the core power supply voltage being greater than the second reference voltage.

19. The method of claim 18, wherein the second reference voltage is greater than the first reference voltage.

20. The method of claim 18, wherein the first reference voltage approximately equals 0.55V and the second reference voltage approximately equals 0.75V.

21. A memory, comprising:
a memory power supply voltage rail for a memory power supply voltage;
a core power supply voltage rail for a core power supply voltage;
a voltage regulator coupled to the memory power supply voltage rail and the core power supply voltage rail, wherein the voltage regulator regulates a bit line power supply voltage;
a bit line power supply voltage rail for the bit line power supply voltage;
a bit line;
a bitcell including a first inverter and a first access transistor, wherein the first inverter includes a first p-type metal-oxide semiconductor (PMOS) transistor having a source coupled to the memory power supply voltage rail, and wherein the first access transistor couples between an output node of the first inverter and the bit line;
a core periphery coupled to the core power supply voltage rail; and
a write driver including a second PMOS transistor having a source coupled to the bit line power supply voltage rail and a drain coupled to the bit line.

22. The memory of claim 21, wherein the write driver further includes an NMOS transistor having a source coupled to ground and a drain coupled to the drain of the second PMOS transistor.

23. The memory of claim 21, further comprising:
a column multiplexer, wherein the drain of the second PMOS transistor is coupled to the bit line through the column multiplexer.

24. The memory of claim 21, further comprising:
a word line;
a row decoder powered by a bit line power supply voltage from the bit line power supply voltage rail and configured to select for the word line during a write operation to the memory; and
a word line driver configured to charge the word line to the memory power supply voltage.

25. The memory of claim 21, wherein the memory is included within a system-on-a-chip.

26. The memory of claim 25, wherein the system-on-a-chip is included within a cellular telephone.
